(19) United States
(12) Patent Application Publication
(10) Pub. No.: US 2026/0303072 A1
(43) Pub. Date: Oct. 1, 2026

(54) SYNCHRONOUS CIRCUIT

(71) Applicant: STMicroelectronics International N.V., Geneva (CH)

(72) Inventors: Riccardo CONDORELLI, Tremestieri Etneo/Catania (IT); Salvatore COSTA, Siracusa (IT)

(73) Assignee: STMicroelectronics International N.V., Geneva (CH)

(21) Appl. No.: 19/566,083

(22) Filed: Mar. 13, 2026

(30) Foreign Application Priority Data
Mar. 25, 2025 (FR) FR2503061

(51) Int. Cl. H03K 3/037; H03K 3/012

(52) U.S. Cl. CPC H03K 3/037; H03K 3/012

(57) ABSTRACT

The present disclosure relates to a synchronous circuit including a plurality of flip-flops, and providing an updated output at each edge of a first type of a first clock signal. A first circuit includes first flip-flops of the plurality of flip-flops, synchronized on a first type of edges of a second clock signal having half the frequency of the first clock signal. The first circuit provides a first output updated at each first type edge of the second clock signal. A second circuit includes second flip-flops of the plurality of flip-flops, synchronized on a second type of edges of the second clock signal. The second circuit provides a second output updated at each second type edge of the second clock signal. A combinational circuit receives the first and second output and provides the output of the synchronous circuit.

### PRIORITY CLAIM

This application claims the priority benefit of French Application for Patent No. FR2503061 filed on Mar. 25, 2025, the content of which is hereby incorporated by reference in its entirety to the maximum extent allowable by law.

### TECHNICAL FIELD

The present disclosure relates generally to electronic circuits, in particular integrated circuits. The present disclosure relates more particularly to synchronous electronic circuits.

### BACKGROUND

In known synchronous circuits, a clock signal is distributed to a plurality of synchronous flip-flops, generally D flip-flops, that are synchronized on the edges of the clock signal, usually on the same type of edge of the clock signal, for example on rising edges.

In such known synchronous circuits, each flip-flop of the plurality of flip-flops updates its output with the data present on its data input at each edge of the same type, for example rising, of the clock signal that is received by its synchronization input. This allows the circuit to provide output data updated at each edge of this type of the clock signal.

As all the flip-flops of the plurality of flip-flops are updated on the same type of edge of the clock signal, all these flip-flops have a power consumption peak at each of these edges, which results in a voltage drop in the power supply voltage of the flip-flops.

Further, in such known circuits, the power consumption is related to the frequency of the clock signal. Thus, reducing the frequency of the clock signal allows a reduction in the power consumption of the circuit. However, reducing the frequency of the clock signal may be impossible when the circuit has to process input data that comes from another circuit, or when it has to provide output data to another circuit.

There is a need for a synchronous circuit having a plurality of flip-flops that addresses all or some of the drawbacks of known synchronous circuits having a plurality of flip-flops synchronized on the same type of edge of a clock signal, and that provides output data updated at each of these edges.

### SUMMARY

One embodiment addresses all or some of the drawbacks of known circuits having a plurality of flip-flops synchronized on the same type of edge of a clock signal, and providing output data updated at each of these edges.

One embodiment provides a synchronous circuit comprising a plurality of flip-flops and configured to provide an updated output at each edge of a first type of a first clock signal. The synchronous circuit comprises a first circuit comprising first flip-flops of the plurality of flip-flops, the first flip-flops being synchronized and updated on a first type of edge of a second clock signal having a frequency equal to half of the frequency of the first clock signal, the first circuit being configured to provide a first output updated at each first-type edge of the second clock signal. The synchronous circuit further comprises a second circuit comprising second flip-flops of the plurality of flip-flops, the second flip-flops being synchronized and updated on a second type of edge of the second clock signal, the second circuit being configured to provide a second output updated at each second-type edge of the second clock signal. The synchronous circuit further comprises a combinational circuit receiving the first and second outputs and configured to provide the output of the synchronous circuit based on the first and second outputs.

According to one embodiment, the number of first flip-flops is equal to the number of second flip-flops.

According to one embodiment, the first circuit comprises more than one first flip-flop, and the second circuit comprises more than one second flip-flop.

According to one embodiment, the first and second circuits each have the same functionality.

According to one embodiment, each first flip-flop is configured to maintain its output between two successive updates of said first flip-flop, and each second flip-flop is configured to maintain its output between two successive updates of said second flip-flop.

According to one embodiment, the first flip-flops are series-connected in the first circuit, and the second flip-flops are series-connected in the second circuit.

According to one embodiment, the first output is determined by at least one output of the first flip-flops, and the second output is determined by at least one output of the second flip-flops.

According to one embodiment, the synchronous circuit is a synchronous counter.

According to one embodiment, the first circuit is a first synchronous counter, the second circuit is a second synchronous counter, and the combinational circuit is an adder circuit configured to add the first and second outputs and to provide the output of the synchronous circuit equal to the result of the addition.

According to one embodiment, the first circuit comprises, for each first flip-flop, a circuit providing an input of said first flip-flop based on at least one output among the outputs of the first flip-flops, said at least one output comprising the output of said first flip-flop; and the second circuit comprises, for each second flip-flop, a circuit providing an input of said second flip-flop based on at least one output among the outputs of the second flip-flops, said at least one output comprising the output of said second flip-flop.

According to one embodiment, the synchronous circuit is a shift register.

According to one embodiment, the first circuit is a first shift register, the second circuit is a second shift register, and the combinational circuit is configured to provide the output of the synchronous circuit equal to the first output of the first circuit when the second clock signal is in a state following each edge of the second type of the second clock signal, and equal to the second output of the second circuit when the second clock signal is in a state following each edge of the first type of the second clock signal.

According to one embodiment, the first flip-flops are series-connected, a first one of the first flip-flops has an input receiving an input of the synchronous circuit, and each of the other first flip-flops has an input connected to an output of the previous first flip-flop, a last one of the first flip-flops having an output providing the first output; and the second flip-flops are series-connected, a first one of the second flip-flops has an input receiving the input of the synchronous circuit, and each of the other second flip-flops has an input connected to an output of the previous second flip-flop, a last one of the second flip-flops having an output providing the second output.

A further embodiment provides a system comprising an emitting circuit configured to provide first data updated at each edge of the first type of the first clock signal, a receiving circuit configured to receive second data updated at each edge of the first type of the first clock signal, and the synchronous circuit, which is a synchronous shift register as defined above.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1 illustrates an example of a synchronous circuit having a plurality of flip-flops.

FIG. 2 illustrates a drawback of the circuit of FIG. 1.

FIG. 3 illustrates an embodiment of a synchronous circuit.

FIG. 4 illustrates the operation of the circuit of FIG. 3 compared with the operation of the circuit of FIG. 1.

FIG. 5 illustrates an advantage of the circuit of FIG. 3.

FIG. 6 illustrates an example of a synchronous circuit of the type described in relation to FIG. 1.

FIG. 7 illustrates an example of a synchronous circuit of the type described in relation to FIG. 3.

FIG. 8 illustrates an operation of the circuit of FIG. 7 compared with the operation of the circuit of FIG. 6.

FIG. 9 illustrates another example of a synchronous circuit of the type described in relation to FIG. 1.

FIG. 10 illustrates another example of a synchronous circuit of the type described in relation to FIG. 3.

FIG. 11 illustrates an operation of the circuit of FIG. 10 compared with the operation of the circuit of FIG. 9.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10% or 10°, and preferably within 5% or 5°.

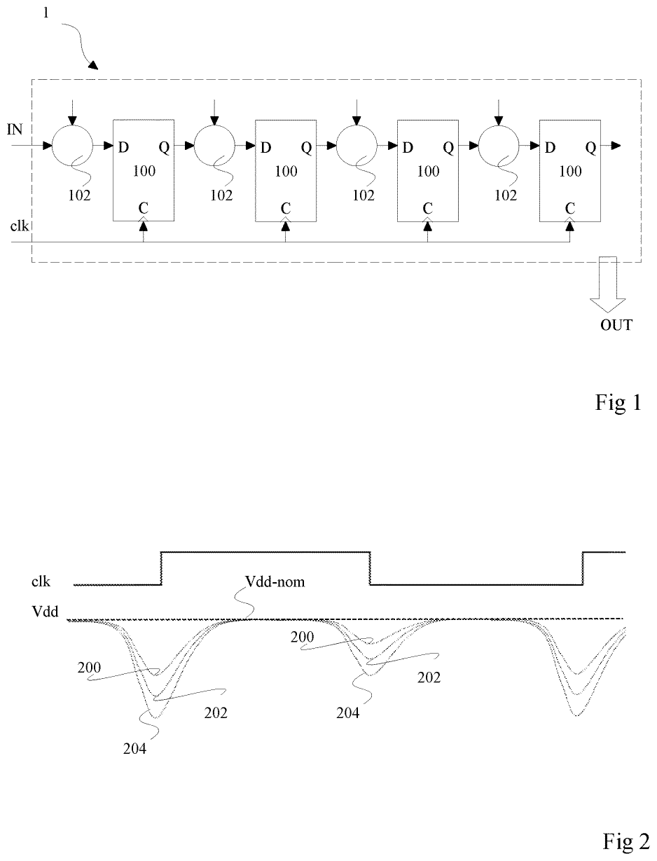

FIG. 1 illustrates, schematically and with blocks, an example of a synchronous circuit 1.

The circuit 1 comprises a plurality of synchronous flip-flops 100, preferably D flip-flops 100. Although not shown in FIG. 1, all the flip-flops 100 are supplied with the same power supply voltage Vdd.

Each flip-flop 100 comprises a data input D, a data output Q, and a synchronization input C. The data input D is configured to receive an input data bit of the flip-flop 100. The data output Q is configured to provide an output data bit of the flip-flop 100. The synchronization input C is configured to receive a clock signal. The flip-flop 100 is configured to update its output Q with its input D (to copy its inputs D on its output Q) at each edge of the same type, for example at each rising edge, of the clock signal received by its synchronization input C. The flip-flop 100 is further configured to maintain, or memorize, its output Q between two successive updates of the output.

In the circuit 1, all the flip-flops 100 are configured to update their respective outputs Q at each edge of the same type, for example rising, of a clock signal clk. For example, in FIG. 1, all the synchronization inputs C are sensitive to rising edges, and the synchronization inputs C receive the signal clk.

The flip-flops 100 of the circuit 1 are series-coupled. In other words, each flip-flop 100, except the first one of the succession of series-coupled flip-flops 100, receives on its input D an input data that is at least partly determined by the output data of the previous flip-flop 100 of the succession. The first one of the series-coupled flip-flops 100 receives on its input D an input data that is at least partly determined by an input data IN of the circuit 1 or by its own output data. Thus, the input IN may be absent when the input of the first flip-flop 100 of the succession is determined by the output Q of this flip-flop 100.

In the example of FIG. 1, the circuit 1 comprises, for each flip-flop 100, an associated circuit 102 providing the input data of the flip-flop 100.

The circuits 102 are combinational circuits, or, in other words, do not comprise any flip-flop, latch, or memorizing element.

In another example not shown, the flip-flops 100 are series-connected, and, for each flip-flop 100 of the succession of series-connected flip-flops except the first one, the input D of the flip-flop 100 is connected to the output Q of the previous flip-flop 100 in the succession, and each circuit 102 then corresponds to a simple connecting wire.

The circuit 1 is configured to provide an output data OUT that is updated at each edge of the same type of the clock signal clk, for example at each rising edge. The circuit 1 is further configured to maintain its output OUT stable between two successive updates of this output OUT, or, in other words, between two successive edges of the same type of the signal clk.

The output OUT may be determined by the output Q of the last flip-flop 100 of the succession of flip-flops 100. For example, the output OUT is the output Q of the last flip-flop 100.

Alternatively, the output OUT may be determined by at least one of the outputs Q of the flip-flops 100, for example by all the outputs Q of the flip-flops 100. For example, the output OUT is the concatenation of the outputs Q of the flip-flops 100.

As an example, the circuit 1 may be a synchronous shift register. As another example, the circuit 1 may be a synchronous counter. As a further example, the circuit 1 may be a linear feedback shift register (LFSR). More generally, the circuit 1 may be any circuit based on a synchronous shift register or a synchronous counter.

As previously indicated, the power consumption of the circuit 1 is related to the frequency of the signal clk. Indeed, the higher the frequency of the signal clk, the higher the power consumption.

When it is desired to decrease the power consumption, those skilled in the art may consider reducing the frequency of the signal clk. However, when the circuit 1 is part of an electronic system and receives, from another circuit of the system, an input IN that is updated at a first frequency and/or provides, to another circuit of the system, an output OUT that is updated at the first frequency, lowering the frequency of the signal clk with respect to the first frequency renders the system non-functional.

FIG. 2 illustrates the operation of the circuit 1 of FIG. 1. More particularly, FIG. 2 represents the signal clk of the circuit 1 and the power supply voltage Vdd of the flip-flops 100 of the circuit 1. In the example of FIG. 2, the output OUT is updated at each rising edge of the signal clk and is maintained between two successive updates.

More particularly, a curve 200 illustrates the evolution of the voltage Vdd with respect to a nominal value Vdd-nom when the circuit 1 comprises N flip-flops 100, with N being an integer greater than or equal to 2, a curve 202 illustrates the evolution of the voltage Vdd when the circuit 1 comprises 2·N flip-flops 100, and a curve 204 illustrates the evolution of the voltage Vdd when the circuit 1 comprises 3·N flip-flops 100.

As can be seen in FIG. 2, at each rising edge of the signal clk, the voltage Vdd drops because of the power drawn by the flip-flops 100 to update their outputs Q. The higher the number of flip-flops 100 in the circuit 1, the greater the voltage drop.

As can also be seen in FIG. 2, at each falling edge of the signal clk, the voltage Vdd also drops, but to a lesser extent than at the rising edges. This drop in the voltage Vdd is, for example, due to the propagation of the clock edge in the clock tree.

Such drops in the voltage Vdd degrade the performance of the circuit 1 and of the system comprising the circuit 1. Indeed, in addition to the flip-flops 100, the signal clk is generally provided to many other flip-flops similar to the flip-flops 100, via a clock tree comprising delay cells for ensuring that all the flip-flops simultaneously receive the edges of the signal clk. However, variations in the voltage Vdd, and in particular drops in the voltage Vdd, modify the delay introduced by each delay cell of the clock tree, which unbalances the propagation of the signal clk in the clock tree and may result in malfunctions of the circuit 1 or of the system comprising the circuit 1.

Thus, there is a need to reduce the drops of the voltage Vdd at the rising edges of the signal clk when the output OUT is updated at each rising edge of the signal clk.

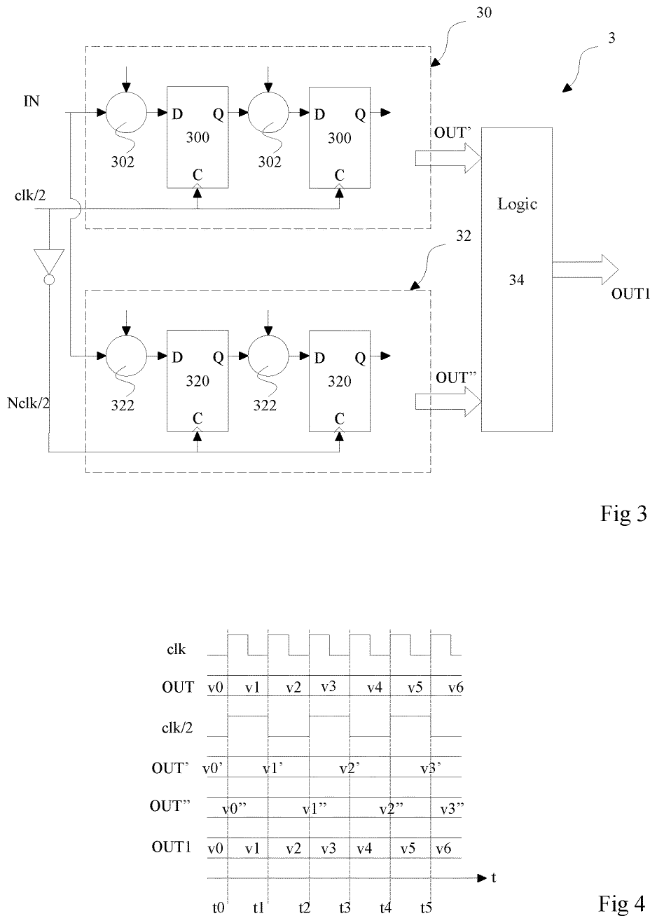

FIG. 3 illustrates an embodiment of a synchronous circuit 3.

The synchronous circuit 3 is configured, like the circuit 1, to provide an output OUT1 updated at each edge of the same type of the clock signal clk, for example at each rising edge of the signal clk. The circuit 3 is further configured to maintain its output OUT1 stable between two successive updates of this output OUT1, or, in other words, between two successive rising edges of the signal clk.

The synchronous circuit 3 comprises a plurality of flip-flops 300 and 320 identical to the flip-flops 100 described in relation to FIG. 1, except that they are not sensitive to the rising edges of the signal clk, or, in other words, they are not configured to update their respective outputs Q at each rising edge of the signal clk.

More particularly, the circuit 3 comprises a circuit 30 comprising part of the plurality of flip-flops of the circuit 3, and a circuit 32 comprising another part of the plurality of flip-flops of the circuit 3, the flip-flops of the circuit 30 and 32 being referenced 300 and 320, respectively.

Preferably, the circuit 30, respectively 32, comprises more than one flip-flop 300, respectively 320.

Preferably, the number of flip-flops 300 is equal to the number of flip-flops 320. For example, to implement a synchronous shift register that has a shift between its input and its output equal to 2·N+1 cycles of the signal clk, with N being a strictly positive integer, each of the circuits 30 and 32 has N flip-flops, and the remaining flip-flop is added at the input IN or at the output OUT of the circuit 3 and is synchronized on the clock signal clk. As another example, to implement a synchronous shift register that has a shift between its input and its output equal to 2·N cycles of the signal clk, each of the circuits 30 and 32 has N flip-flops. As yet another example, when the circuit 3 implements a synchronous counter, the number of flip-flops is the same in each of the circuits 30 and 32.

The flip-flops 300 are synchronized on, or sensitive to, a first type of edge of a clock signal clk/2 having a frequency equal to half the frequency of the clock signal clk. In other words, each flip-flop 300 is configured to update its output Q with its input D at each edge of the first type of the signal clk/2. Each flip-flop 300 is further configured to maintain its output Q between two successive updates of its output Q, or, in other words, between two successive edges of the first type of the signal clk/2.

The flip-flops 320 are synchronized on, or sensitive to, a second type of edge of the clock signal clk/2. In other words, each flip-flop 320 is configured to update its output Q with its input D at each edge of the second type of the signal clk/2. Each flip-flop 320 is further configured to maintain its output Q between two successive updates of its output Q, or, in other words, between two successive edges of the second type of the signal clk/2.

Each edge of the first type of the signal clk/2 is synchronized with a corresponding edge of the signal clk, and each edge of the second type of the signal clk/2 is also synchronized with a corresponding edge of the signal clk. The edges of the signal clk with which the edges of the first and second types of the signal clk/2 are synchronized are of the same type, for example rising edges, the output OUT1 of the circuit 3 being updated on each of these edges of the signal clk.

In the example of FIG. 3, the first type of edge of the signal clk/2 is a rising edge, and the second type of edge of the signal clk/2 is a falling edge.

In the example of FIG. 3, each flip-flop 300 and 320 has its synchronization input C sensitive to rising edges of the signal received by this input. Thus, in this example, each flip-flop 300 receives the signal clk/2 at its input C, and each flip-flop 320 receives the binary complement of the signal clk/2, referenced Nclk/2 in FIG. 3, at its input C.

In alternative examples not shown, each flip-flop 300 may have its synchronization input C sensitive to falling edges of the signal received by this input, and/or each flip-flop 320 may have its synchronization input C sensitive to falling edges of the signal received by this input. Those skilled in the art would then be capable of adapting the signal received by the synchronization inputs C of the flip-flops 300 and/or the signal received by the synchronization inputs C of the flip-flops 320, so that the flip-flops 300 are updated on the first type of edge of the signal clk/2 and the flip-flops 320 are updated on the second type of edge of the signal clk/2.

According to one embodiment, the flip-flops 300, respectively 320, of the circuits 30, respectively 32, are series-coupled. In other words, each flip-flop 300, respectively 320, except the first one of the succession of series-coupled flip-flops 300, respectively 320, receives on its input D an input data that is at least partly determined by the output data of the previous flip-flop 300, respectively 320, of the succession. The first one of the series-coupled flip-flops 300, respectively 320, receives on its input D an input data that is at least partly determined by an input data IN of the circuit 3 or by its own output data. Thus, the input IN may be absent when the input of the first flip-flop 300, respectively 320, of the succession is determined by the output Q of this flip-flop 300, respectively 320.

In the example of FIG. 3, the flip-flops 300, respectively 320, are series-coupled, and the circuit 30, respectively 32, comprises, for each flip-flop 300, respectively 320, an associated circuit 302, respectively 322, providing the input data of this flip-flop 300, respectively 320. For example, for each flip-flop 300, respectively 320, except the first one of the succession, the circuit 302, respectively 322, associated with this flip-flop 300, respectively 320, is configured to determine the input data of this flip-flop at least partly based on the output data of the previous flip-flop 300, respectively 320, of the succession. For example, the circuit 302, respectively 322, associated with the first one of the series-coupled flip-flops 300, respectively 320, is configured to determine the input data of this flip-flop at least partly based on an input data IN of the circuit 3 or on the output data of this flip-flop.

The circuits 302 and 322 are combinational circuits, or, in other words, do not comprise any flip-flop, latch, or memorizing element.

In another example not shown, the flip-flops 300, respectively 320, are series-connected, and, for each flip-flop 300, respectively 320, of the succession of series-connected flip-flops except the first one, the input D of this flip-flop 300, respectively 320, is connected to the output Q of the previous flip-flop 300, respectively 320, in the succession, and each circuit 302, respectively 322, then corresponds to a simple connecting wire.

The circuit 30, respectively 32, is configured to provide an output data OUT′, respectively OUT″, that is updated at each edge of the first type, respectively of the second type, of the clock signal clk/2. For example, the circuit 30, respectively 32, is configured to provide an output data OUT′, respectively OUT″, that is updated at each rising edge of the signal clk/2, respectively at each falling edge of the signal clk/2.

The circuit 30, respectively 32, is further configured to maintain its output OUT′, respectively OUT″, stable between two successive updates of this output. In particular, the output OUT′, respectively OUT″, is never updated on an edge of the second type, respectively of the first type, of the signal clk/2.

The output OUT′ may be determined by the output Q of the last flip-flop 300 of the succession of flip-flops 300. For example, the output OUT′ is the output bit of this last flip-flop 300. Similarly, the output OUT″ may be determined by the output Q of the last flip-flop 320 of the succession of flip-flops 320. For example, the output OUT″ is the output bit of this last flip-flop 320.

Alternatively, the output OUT′ may be determined by at least one of the outputs Q of the flip-flops 300, for example by all the outputs Q of the flip-flops 300. For example, the output OUT′ is the concatenation of the outputs Q of the flip-flops 300. Similarly, the output OUT″ may be determined by at least one of the outputs Q of the flip-flops 320, for example by all the outputs Q of the flip-flops 320. For example, the output OUT″ is the concatenation of the outputs Q of the flip-flops 320.

Preferably, both circuits 30 and 32 have the same functionality. For example, both circuits 30 and 32 are synchronous shift registers. As another example, both circuits 30 and 32 are synchronous counters. As another example, both circuits 30 and 32 are part of a linear feedback shift register.

Although not shown in FIG. 3, all the flip-flops 300 and 320 are supplied with the same power supply voltage Vdd.

The circuit 3 further comprises a combinational logic circuit 34. The circuit 34 receives the outputs OUT′ and OUT″ of the respective circuits 30 and 32, and is configured to provide the output OUT1 of the circuit 3 based on the received outputs OUT′ and OUT″. The circuit 34 is preferably purely combinational and thus does not comprise any memorizing element such as a flip-flop or a latch.

FIG. 4 illustrates the operation of the circuit of FIG. 3 compared with the operation of the circuit 1 of FIG. 1.

More particularly, FIG. 4 shows an example of the evolution over time t of the following signals: the clock signal clk; the output OUT of the circuit 1 of FIG. 1; the clock signal clk/2; the output OUT′ of the circuit 30 of FIG. 3; the output OUT″ of the circuit 32 of FIG. 3; and the output OUT1 of the circuit 3 of FIG. 3.

In the example of FIG. 4, the circuit 1 is configured to update its output OUT at each rising edge of the signal clk, the circuit 30 is configured to update its output OUT′ at each rising edge of the signal clk/2, and the circuit 32 is configured to update its output OUT″ at each falling edge of the signal clk/2. Further, in FIG. 4, the rising edges of the signal clk/2 are synchronized with corresponding rising edges of the signal clk. For example, although not shown in FIG. 3, the circuit 3 may comprise a frequency divider by two receiving the signal clk and providing the signal clk/2, the signal Nclk/2 being, for example, provided by an inverter circuit of the circuit 3 that receives the signal clk/2.

Before an instant t0, the outputs OUT, OUT′, OUT″, and OUT1 have the respective values v0, v0′, v0″, and v0, the value v0 of the output OUT1 being determined by the circuit 34 based on the values v0′ and v0″ and being equal to the value v0 of the output OUT.

At the instant t0, the signals clk and clk/2 both transition from a low state to a high state. The rising edge of the signal clk results in the output OUT being updated with the value v1, and the rising edge of the signal clk/2 results in the output OUT′ being updated with the value v1′. The output OUT″ remains at its current value v0″. The value OUT1 then changes from the value v0, determined by the values v0′ and v0″, to the value v1, determined by the values v1′ and v0″.

At an instant t1 following the instant t0, the signal clk transitions from a low state to a high state, and the signal clk/2 transitions from a high state to a low state. The rising edge of the signal clk results in the output OUT being updated with the value v2, and the falling edge of the signal clk/2 results in the output OUT″ being updated with the value v1″, whereas the output OUT′ remains at its current value v1′. The value OUT1 then changes from the value v1 determined by the values v1′ and v0″, to the value v2 determined by the values v1′ and v1″.

At an instant t2 following the instant t1, the signals clk and clk/2 both transition from a low state to a high state. The rising edge of the signal clk results in the output OUT being updated with the value v3, and the rising edge of the signal clk/2 results in the output OUT′ being updated with the value v2′, whereas the output OUT″ remains at its current value v1″. The value OUT1 changes from the value v2 to the value v3, determined by the values v2′ and v1″.

At an instant t3 following the instant t2, the signal clk transitions from a low state to a high state, and the signal clk/2 transitions from a high state to a low state. The rising edge of the signal clk results in the output OUT being updated with the value v4, and the falling edge of the signal clk/2 results in the output OUT″ being updated with the value v2″, whereas the output OUT′ remains at its current value v2′. The value OUT1 changes from the value v3 to the value v4, determined by the values v2′ and v2″.

At an instant t4 following the instant t3, the signals clk and clk/2 both transition from a low state to a high state. The rising edge of the signal clk results in the output OUT being updated with the value v5, and the rising edge of the signal clk/2 results in the output OUT′ being updated with the value v3′, whereas the output OUT″ remains at its current value v2″. The value OUT1 changes from the value v4 to the value v5, determined by the values v3′ and v2″.

At an instant t5 following the instant t4, the signal clk transitions from a low state to a high state, and the signal clk/2 transitions from a high state to a low state. The rising edge of the signal clk results in the output OUT being updated with the value v6, and the falling edge of the signal clk/2 results in the output OUT″ being updated with the value v3″, whereas the output OUT′ remains at its current value v3′. The value OUT1 changes from the value v5 to the value v6, determined by the values v3′ and v3″.

As can be seen in FIG. 4, the output OUT1 is updated at each rising edge of the signal clk, similarly to the output OUT. Further, at each rising edge of the signal clk, both outputs OUT and OUT1 are updated with identical values. The circuits 1 and 3 thus have output signals OUT and OUT1 that are identical.

However, in the circuit 3, the updates of the flip-flops 300 and 320 occur at a frequency two times lower than the update frequency of the flip-flops 100 of the circuit 1. Thus, the power consumption of the circuit 3 is reduced with respect to the power consumption of the circuit 1.

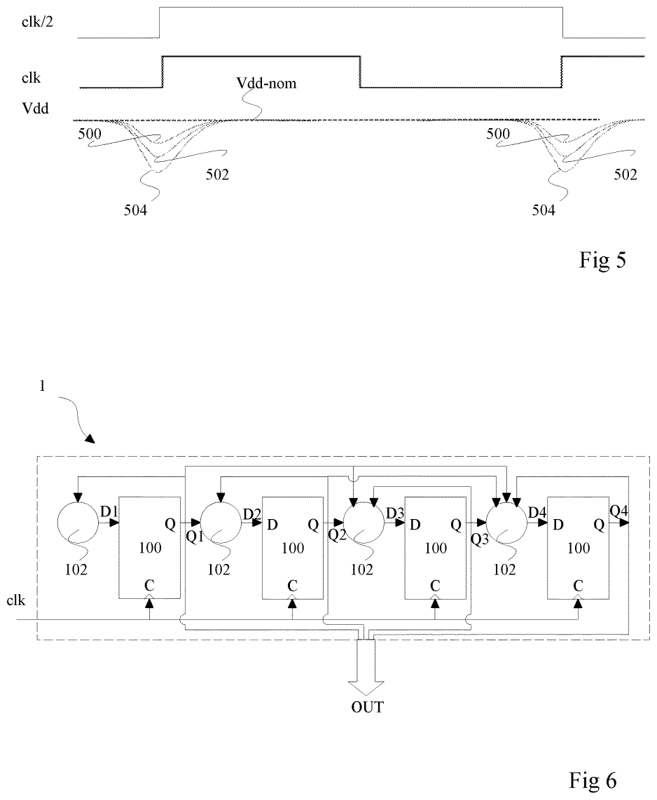

FIG. 5 illustrates an advantage of the circuit 3 of FIG. 3 compared with the circuit 1 of FIG. 1. More particularly, FIG. 5 represents the signal clk of the circuit 1, the signal clk/2 of the circuit 3, and the power supply voltage Vdd of the flip-flops 300 and 320 of the circuit 3. In the example of FIG. 5, the output OUT′ is updated at each rising edge of the signal clk/2 and is not updated at the falling edges of the signal clk/2, whereas the output OUT″ is updated at each falling edge of the signal clk/2 and is not updated at the rising edges of the signal clk/2.

More particularly, a curve 500 illustrates the evolution of the voltage Vdd with respect to a nominal value Vdd-nom when the circuit 3 comprises a total number N of flip-flops 300 and 320 equal to the number N of flip-flops 100 corresponding to the curve 200 of FIG. 2. A curve 502 illustrates the evolution of the voltage Vdd when the circuit 3 comprises a total number of flip-flops 300 and 320 equal to 2·N. A curve 504 illustrates the evolution of the voltage Vdd when the circuit 3 comprises a total number of flip-flops 300 and 320 equal to 3·N.

As can be seen in FIG. 5, at each rising edge of the signal clk/2, the voltage Vdd drops because of the power drawn by the flip-flops 300 to update their outputs Q. The higher the number of flip-flops 300 in the circuit 3, the greater the voltage drop.

However, for a same number N of flip-flops in the circuit 1 and in the circuit 3, the voltage drop ΔVdd in the circuit 3 at each rising edge of the signal clk/2 is lower than the voltage drop ΔVdd in the circuit 1 at each rising edge of the signal clk shown in FIG. 2.

This results from the fact that, at each rising edge of the signal clk/2, only the flip-flops 300 are updated in the circuit 3, whereas, in the circuit 1, at each rising edge of the signal clk, all the flip-flops 100 are updated.

Further, at each falling edge of the signal clk, there is no drop in the voltage Vdd in the circuit 3 because none of the flip-flops 300 or 320 is updated at this edge.

As can also be seen in FIG. 5, at each falling edge of the signal clk/2, the voltage Vdd drops because of the power drawn by the flip-flops 320 to update their outputs Q. The higher the number of flip-flops 320 in the circuit 3, the greater the voltage drop.

However, for a same number N of flip-flops in the circuit 1 and in the circuit 3, the voltage drop ΔVdd in the circuit 3 at each falling edge of the signal clk/2 is lower than the voltage drop ΔVdd in the circuit 1 at each rising edge of the signal clk shown in FIG. 2.

This results from the fact that, at each falling edge of the signal clk/2, only the flip-flops 320 are updated in the circuit 3, whereas, in the circuit 1, at each rising edge of the signal clk, all the flip-flops 100 are updated.

In fact, in the circuit 3, for a given number N of flip-flops 300 and 320, the voltage drop at each rising edge of the signal clk/2 is substantially similar to the voltage drop at each falling edge of the signal clk/2, and these voltage drops are lower than the voltage drop at each rising edge of the signal clk in the circuit 1 having N flip-flops 100.

Thus, the circuit 3 advantageously allows a reduction of the voltage drops of the supply voltage Vdd compared with a corresponding circuit 1.

The advantages regarding power consumption and voltage drops ΔVdd described above for the circuit 3 with respect to the circuit 1 also apply when the total number of flip-flops in the circuit 3 is greater than the number of flip-flops in the circuit 1, for example when the total number of flip-flops in the circuit 3 is equal to the number of flip-flops in the circuit 1 plus one, or plus two. For example, the number of flip-flops in the circuit 3 may be greater by two than the number of flip-flops in the circuit 1 when both circuits 1 and 3 implement a synchronous counter configured to count to the same number.

FIG. 6 illustrates the synchronous circuit 1 in an example where the circuit 1 is a synchronous counter.

In the example of FIG. 6, the flip-flops 100 are updated at each rising edge of the signal clk and maintain their respective outputs between two successive rising edges of the signal clk.

In the example of FIG. 6, the circuit 1 comprises four flip-flops 100 that are series-coupled. The first flip-flop 100 of the succession of flip-flops 100 (located on the left in FIG. 6) receives an input D1 and provides an output Q1. The second flip-flop 100 receives an input D2 and provides an output Q2. The third flip-flop 100 receives an input D3 and provides an output Q3. The fourth, or last, flip-flop 100 receives an input D4 and provides an output Q4.

In this example, where the circuit 1 is a synchronous counter, the output OUT of the circuit 1 is the concatenation of the outputs Q1, Q2, Q3, and Q4.

In this example, where the circuit 1 is a synchronous counter, the circuit 1 does not receive any input IN.

In one example implementation, a first circuit 102 receives the output Q1 and provides the input D1 equal to the Boolean negation of the output Q1. A second circuit 102 receives the outputs Q1 and Q2 and provides the input D2 equal to a Boolean exclusive-OR (XOR) of the outputs Q1 and Q2. A third circuit 102 receives the outputs Q1, Q2, and Q3 and provides the input D3 equal to a Boolean exclusive-OR (XOR) of the output Q3 and the Boolean AND of the outputs Q1 and Q2. A fourth circuit 102 receives the outputs Q1, Q2, Q3, and Q4 and provides the input D4 equal to a Boolean exclusive-OR (XOR) of the output Q4 and the Boolean AND of the outputs Q1, Q2, and Q3.

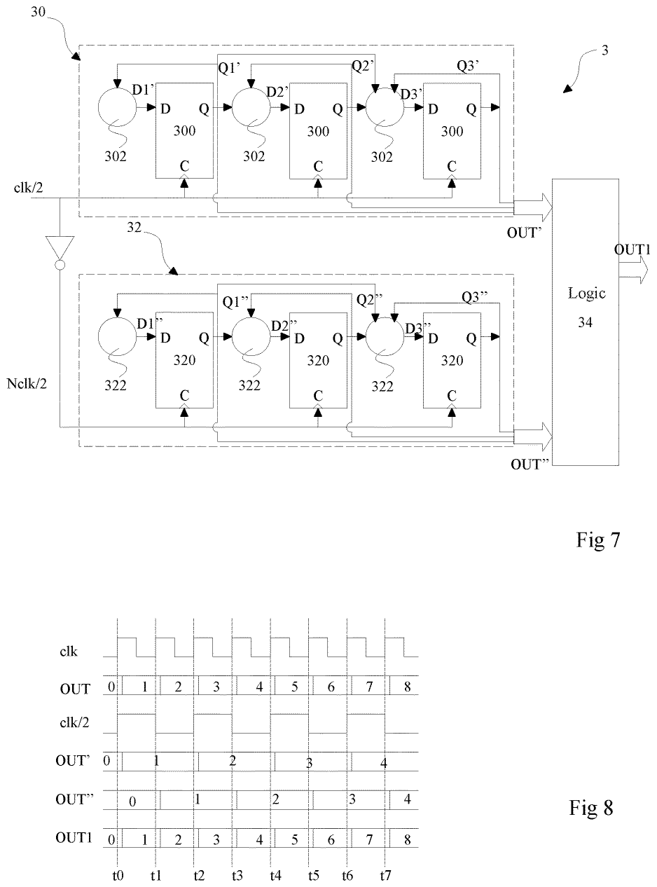

FIG. 7 illustrates the synchronous circuit 3 in an example where the circuit 3 is a synchronous counter. Unless specified otherwise, all descriptions provided for the circuit 3 in FIG. 3 apply equally to the circuit 3 of FIG. 7.

When the circuit 3 is a synchronous counter, the circuits 30 and 32 are two synchronous counters, for example identical to each other. Further, the circuit 34 is preferably an adder circuit configured to add the outputs OUT′ and OUT″ and to provide the output OUT1 equal to the sum of the outputs OUT′ and OUT″.

For example, the circuit 30 comprises, for each flip-flop 300, a circuit 302 associated with this flip-flop 300 and configured to provide an input data to this flip-flop 300 based on at least one of the outputs of the flip-flops 300, the at least one output comprising the output of the flip-flop 300 with which the circuit 302 is associated. Similarly, the circuit 32 comprises, for each flip-flop 320, a circuit 322 associated with this flip-flop 320 and configured to provide an input data to this flip-flop 320 based on at least one of the outputs of the flip-flops 320, the at least one output comprising the output of the flip-flop 320 with which the circuit 322 is associated.

In the example of FIG. 7, the synchronous counter 3 is configured to count to at least the same maximum value as the synchronous counter 1 of FIG. 6. Thus, in this example, the circuit 3 comprises six flip-flops, more particularly three flip-flops 300 series-coupled in the circuit 30, and three flip-flops 320 series-coupled in the circuit 32.

In the circuit 30, the first flip-flop 300 of the succession of flip-flops 300 (located on the left in FIG. 7) receives an input D1′ and provides an output Q1′. The second flip-flop 300 receives an input D2′ and provides an output Q2′. The third, or last, flip-flop 300 receives an input D3′ and provides an output Q3′. For example, a first circuit 302 receives the output Q1′ and provides the input D1′ equal to the Boolean negation of Q1′. A second circuit 302 receives the outputs Q1′ and Q2′ and provides the input D2′ equal to a Boolean exclusive-OR (XOR) of Q1′ and Q2′. A third circuit 302 receives the outputs Q1′, Q2′, and Q3′ and provides the input D3′ equal to a Boolean exclusive-OR (XOR) of Q3′ and the Boolean AND of Q1′ and Q2′.

In the circuit 32, the first flip-flop 320 of the succession of flip-flops 320 (located on the left in FIG. 7) receives an input D1″ and provides an output Q1″. The second flip-flop 320 receives an input D2″ and provides an output Q2″. The third, or last, flip-flop 320 receives an input D3″ and provides an output Q3″. For example, a first circuit 322 receives the output Q1″ and provides the input D1″ equal to the Boolean negation of Q1″. A second circuit 322 receives the outputs Q1″ and Q2″ and provides the input D2″ equal to a Boolean exclusive-OR (XOR) of Q1″ and Q2″. A third circuit 322 receives the outputs Q1″, Q2″, and Q3″ and provides the input D3″ equal to a Boolean exclusive-OR (XOR) of Q3″ and the Boolean AND of Q1″ and Q2″.

In this example, where the circuit 3 is a synchronous counter, the output OUT′ of the circuit 30 is the concatenation of the outputs Q1′, Q2′, and Q3′, and the output OUT″ of the circuit 32 is the concatenation of the outputs Q1″, Q2″, and Q3″.

In this example, where the circuit 3 is a synchronous counter, the circuit 3, and thus its circuits 30 and 32, do not receive any input IN.

FIG. 8 illustrates the operation of the circuit 3 of FIG. 7 compared with the operation of the circuit 1 of FIG. 6.

More particularly, FIG. 8 shows an example of the evolution over time t of the following signals: the clock signal clk; the output OUT of the circuit 1 of FIG. 6; the clock signal clk/2; the output OUT′ of the circuit 30 of FIG. 7; the output OUT″ of the circuit 32 of FIG. 7; and the output OUT1 of the circuit 3 of FIG. 7.

In FIG. 8, the updates of the signals OUT, OUT′, OUT″, and OUT1 with respect to the corresponding edges of the signals clk and clk/2 are shown with a delay, in contrast to what has been represented in FIG. 4.

In the example of FIG. 8, the circuit 1 is configured to update its output OUT at each rising edge of the signal clk, the circuit 30 is configured to update its output OUT′ at each rising edge of the signal clk/2, and the circuit 32 is configured to update its output OUT″ at each falling edge of the signal clk/2. Further, in order to better compare the operations of the circuits 1 and 3, in FIG. 8 the rising edges of the signal clk/2 are synchronized with the rising edges of the signal clk. In the example of FIG. 8, eight successive rising edges of the signal clk are shown and referenced t0, t1, t2, t3, t4, t5, t6, and t7.

Before the instant t0, the outputs OUT, OUT′, OUT″, and OUT1 have the respective values 0, 0, 0, and 0, the value 0 of the output OUT1 being equal to the sum of the value 0 of the output OUT′ and the value 0 of the output OUT″, and being equal to the value 0 of the output OUT.

At the instant t0, the rising edge of the signal clk results in the output OUT being updated to the value 1, and the rising edge of the signal clk/2 results in the output OUT′ being updated to the value 1, whereas the output OUT″ remains at its current value 0. The output OUT1 thus changes from the value 0 to the value 1, equal to the sum of the values 1 and 0 of the respective outputs OUT′ and OUT″.

At the instant t1 following the instant t0, the rising edge of the signal clk results in the output OUT being updated to the value 2, and the falling edge of the signal clk/2 results in the output OUT″ being updated to the value 1, whereas the output OUT′ remains at its current value 1. The output OUT1 thus changes from the value 1 to the value 2, equal to the sum of the values 1 and 1 of the respective outputs OUT′ and OUT″.

At the instant t2 following the instant t1, the rising edge of the signal clk results in the output OUT being updated to the value 3, and the rising edge of the signal clk/2 results in the output OUT′ being updated to the value 2, whereas the output OUT″ remains at its current value 1. The output OUT1 thus changes from the value 2 to the value 3, equal to the sum of the values 2 and 1 of the respective outputs OUT′ and OUT″.

At the instant t3 following the instant t2, the rising edge of the signal clk results in the output OUT being updated to the value 4, and the falling edge of the signal clk/2 results in the output OUT″ being updated to the value 2, whereas the output OUT′ remains at its current value 2. The output OUT1 thus changes from the value 3 to the value 4, equal to the sum of the values 2 and 2 of the respective outputs OUT′ and OUT″.

At the instant t4 following the instant t3, the rising edge of the signal clk results in the output OUT being updated to the value 5, and the rising edge of the signal clk/2 results in the output OUT′ being updated to the value 3, whereas the output OUT″ remains at its current value 2. The output OUT1 thus changes from the value 4 to the value 5, equal to the sum of the values 3 and 2 of the respective outputs OUT′ and OUT″.

At the instant t5 following the instant t4, the rising edge of the signal clk results in the output OUT being updated to the value 6, and the falling edge of the signal clk/ 2 results in the output OUT″ being updated to the value 3, whereas the output OUT′ remains at its current value 3. The output OUT1 thus changes from the value 5 to the value 6, equal to the sum of the values 3 and 3 of the respective outputs OUT′ and OUT″.

At the instant t6 following the instant t5, the rising edge of the signal clk results in the output OUT being updated to the value 7, and the rising edge of the signal clk/2 results in the output OUT′ being updated to the value 4, whereas the output OUT″ remains at its current value 3. The output OUT1 thus changes from the value 6 to the value 7, equal to the sum of the values 4 and 3 of the respective outputs OUT′ and OUT″.

At the instant t7 following the instant t6, the rising edge of the signal clk results in the output OUT being updated to the value 8, and the falling edge of the signal clk/2 results in the output OUT″ being updated to the value 4, whereas the output OUT′ remains at its current value 4. The output OUT1 thus changes from the value 7 to the value 8, equal to the sum of the values 4 and 4 of the respective outputs OUT′ and OUT″.

As can be seen in FIG. 8, the output OUT1 is updated at each rising edge of the signal clk, similarly to the output OUT. The circuits 1 and 3 thus have output signals OUT and OUT1 that are identical.

Further, the power consumption of the circuit 3 of FIG. 7 is lower than the power consumption of the circuit 1 of FIG. 6, and the maximum drop of the voltage Vdd is lower in the circuit 3 of FIG. 7 than in the circuit 1 of FIG. 6.

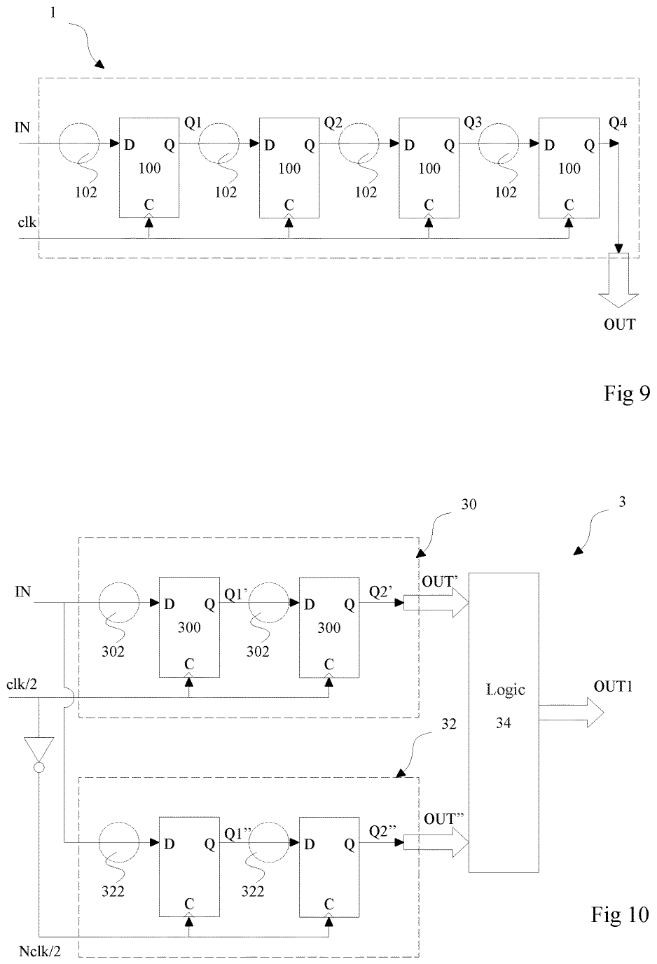

FIG. 9 illustrates the synchronous circuit 1 in an example where the circuit 1 is a synchronous shift register.

In the example of FIG. 9, the flip-flops 100 are updated at each rising edge of the signal clk, and their respective outputs remain at their current values between two successive updates, or, in other words, between two successive rising edges of the signal clk.

In the example of FIG. 9, the circuit 1 comprises four flip-flops 100 that are series-connected. The first flip-flop 100 of the succession of flip-flops 100 (located on the left in FIG. 9) receives the input IN of the circuit 1 and provides an output Q1. The second flip-flop 100 receives the output Q1 as its input data and provides an output Q2. The third flip-flop 100 receives the output Q2 as its input data and provides an output Q3. The fourth, or last, flip-flop 100 receives the output Q3 as its input data and provides an output Q4.

In this example, where the circuit 1 is a synchronous shift register, the output OUT of the circuit 1 is the output Q4 of the last flip-flop 100 of the succession of series-connected flip-flops.

In this example, where the circuit 1 is a synchronous shift register, the circuit 1 receives the input IN.

For example, the circuit 102 associated with the first flip-flop 100 of the succession of series-connected flip-flops 100 (located on the left in FIG. 9) corresponds to a connecting wire between the input D of this flip-flop 100 and the input IN. For each flip-flop 100 except the first one of the succession, the circuit 102 associated with this flip-flop 100 corresponds to a connecting wire between the input D of this flip-flop 100 and the output Q of the previous flip-flop 100 in the succession.

FIG. 10 illustrates the synchronous circuit 3 in an example where the circuit 3 is a synchronous shift register.

When the circuit 3 is a synchronous shift register, the circuits 30 and 32 are two synchronous shift registers, preferably identical to each other. Further, the circuit 34 is, for example, a selection circuit configured to alternatively select the output OUT′ or the output OUT″ based on the state of the signal clk/2. For example, the combinational logic circuit 34 is configured to provide the output OUT1 equal to the output OUT′ after each edge of the signal clk/2 corresponding to an update of the output OUT″, and until the next edge of the signal clk/2, and to provide the output OUT1 equal to the output OUT″ after each edge of the signal clk/2 corresponding to an update of the output OUT′, and until the next edge of the signal clk/2.

In the example of FIG. 10, the synchronous shift register 3 provides an output OUT1 that is shifted by a number of periods of the signal clk with respect to the input IN of the circuit 3 equal to the number of periods by which the output OUT of the circuit 1 of FIG. 9 is shifted with respect to the input IN of that circuit 1. Thus, in this example, the circuit 3 comprises four flip-flops, more particularly two flip-flops 300 series-connected in the circuit 30, and two flip-flops 320 series-connected in the circuit 32.

In the circuit 30, the flip-flops 300 are series-connected. The first flip-flop 300 of the succession (located on the left in FIG. 10) receives the input IN of the circuit 3 at its input D. Each subsequent flip-flop 300 receives, at its input D, the output Q of the preceding flip-flop 300. The output OUT′ corresponds to the output of the last flip-flop 300 (located on the right in FIG. 10).

In the circuit 32, the flip-flops 320 are series-connected. The first flip-flop 320 of the succession (located on the left in FIG. 10) receives the input IN of the circuit 3 at its input D. Each subsequent flip-flop 320 receives, at its input D, the output Q of the preceding flip-flop 320. The output OUT″ corresponds to the output of the last flip-flop 320 (located on the right in FIG. 10).

In the circuit 30 of the example of FIG. 10, the first flip-flop 300 receives the signal IN at its input D and provides an output Q1', and the second, or last, flip-flop 300 receives the output Q1′ at its input D and provides an output Q2′, the signal OUT′ being the output Q2'. Each circuit 302 corresponds to a connecting wire between the input D of the associated flip-flop 300 and either the input IN (for the first flip-flop 300) or the output Q of the preceding flip-flop 300.

In the circuit 32 of the example of FIG. 10, the first flip-flop 320 receives the signal IN at its input D and provides an output Q1″, and the second, or last, flip-flop 320 receives the output Q1″ at its input D and provides an output Q2″, the signal OUT″ being the output Q2″. Each circuit 322 corresponds to a connecting wire between the input D of the associated flip-flop 320 and either the input IN (for the first flip-flop 320) or the output Q of the preceding flip-flop 320.

In the example of FIG. 10, where the flip-flops 300 are updated at each rising edge of the signal clk/2 and the flip-flops 320 are updated at each falling edge of the signal clk/2, the circuit 34 provides the output OUT1 equal to the output OUT′ when the signal clk/2 is low and equal to the output OUT″ when the signal clk/2 is high.

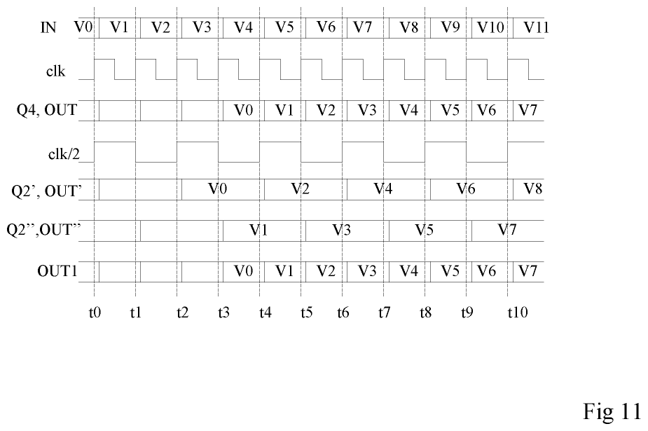

FIG. 11 illustrates the operation of the circuit 3 of FIG. 10 compared with the operation of the circuit 1 of FIG. 9.

More particularly, FIG. 11 shows an example of the evolution over time t of the following signals: the input signal IN applied to the circuit 1 of FIG. 9 and to the circuit 3 of FIG. 10; the clock signal clk; the output OUT (or Q4) of the circuit 1 of FIG. 9; the clock signal clk/2; the output OUT′ (or Q2′) of the circuit 30 of FIG. 10; the output OUT″ (or Q2″) of the circuit 32 of FIG. 10; and the output OUT1 of the circuit 3 of FIG. 10.

In FIG. 11, the updates of the signals OUT, OUT′, OUT″, and OUT1 with respect to the corresponding edges of the signals clk and clk/2 are shown with a delay, in contrast to what has been represented in FIG. 4.

In the example of FIG. 11, the circuit 1 is configured to update its output OUT at each rising edge of the signal clk, the circuit 30 is configured to update its output OUT′ at each rising edge of the signal clk/2, and the circuit 32 is configured to update its output OUT″ at each falling edge of the signal clk/2. Further, in order to better compare the operations of the circuits 1 and 3, in FIG. 11 each rising edge of the signal clk/2 is synchronized with a corresponding rising edge of the signal clk.

In the example of FIG. 11, eleven successive rising edges of the signal clk are shown and referenced t0, t1, t2, t3, t4, t5, t6, t7, t8, t9, and t10.

At the instant t0, corresponding to a rising edge of the signal clk/2, the input signal IN has the value V0. As the circuit 1 of FIG. 9 comprises four flip-flops 100, the output OUT of this circuit 1 is updated with the value V0 at the instant t3. Further, as the circuit 30 is a synchronous shift register comprising two flip-flops 300 synchronized on the rising edges of the signal clk/2, the output OUT′ is updated with the value V0 at the instant t2, corresponding to the rising edge of the signal clk/2 following the rising edge at the instant t0. The output OUT′ remains at the value V0 until its next update.

At the instant t1 following the instant t0, and corresponding to a falling edge of the signal clk/2, the input signal IN has the value V1. The output OUT of the circuit 1 of FIG. 9 is updated with the value V1 at the instant t4. Further, as the circuit 32 is a synchronous shift register comprising two flip-flops 320 synchronized on the falling edges of the signal clk/2, the output OUT″ is updated with the value V1 at the instant t3, corresponding to the falling edge of the signal clk/2 following the falling edge at the instant t1. The output OUT″ remains at the value V1 until its next update.

At the instant t2, corresponding to a rising edge of the signal clk/2, the input signal IN has the value V2. The output OUT of the circuit 1 of FIG. 9 is updated with the value V2 at the instant t5. Further, the output OUT′ is updated with the value V2 at the instant t4, corresponding to the rising edge of the signal clk/2 following the rising edge at the instant t2. The output OUT′ remains at the value V2 until its next update.

At the instant t3 following the instant t2, and corresponding to a falling edge of the signal clk/2, the input signal IN has the value V3. The output OUT of the circuit 1 of FIG. 9 is updated with the value V3 at the instant t6. Further, the output OUT″ is updated with the value V3 at the instant t5, corresponding to the falling edge of the signal clk/2 following the falling edge at the instant t3. The output OUT″ remains at the value V3 until its next update.

At the instant t4 following the instant t3, and corresponding to a rising edge of the signal clk/2, the input signal IN has the value V4. The output OUT of the circuit 1 of FIG. 9 is updated with the value V4 at the instant t7. Further, the output OUT′ is updated with the value V4 at the instant t6, corresponding to the rising edge of the signal clk/2 following the rising edge at the instant t4. The output OUT′ remains at the value V4 until its next update.

At the instant t5 following the instant t4, and corresponding to a falling edge of the signal clk/2, the input signal IN has the value V5. The output OUT of the circuit 1 of FIG. 9 is updated with the value V5 at the instant t8. Further, the output OUT″ is updated with the value V5 at the instant t7, corresponding to the falling edge of the signal clk/2 following the falling edge at the instant t5. The output OUT″ remains at the value V5 until its next update.

At the instant t6 following the instant t5, and corresponding to a rising edge of the signal clk/2, the input signal IN has the value V6. The output OUT of the circuit 1 of FIG. 9 is updated with the value V6 at the instant t9. Further, the output OUT′ is updated with the value V6 at the instant t8, corresponding to the rising edge of the signal clk/2 following the rising edge at the instant t6. The output OUT′ remains at the value V6 until its next update.

At the instant t7 following the instant t6, and corresponding to a falling edge of the signal clk/2, the input signal IN has the value V7. The output OUT of the circuit 1 of FIG. 9 is updated with the value V7 at the instant t10. Further, the output OUT″ is updated with the value V7 at the instant t9, corresponding to the falling edge of the signal clk/2 following the falling edge at the instant t7. The output OUT″ remains at the value V7 until its next update.

Further, between the instants t3 and t4, t5 and t6, t7 and t8, and t9 and t10, the signal clk/2 is low, and the circuit 34 thus provides the output OUT1 equal to the output OUT′. Conversely, between the instants t4 and t5, t6 and t7, and t8 and t9, the signal clk/2 is high, and the circuit 34 thus provides the output OUT1 equal to the output OUT″.

As a result, the output OUT1 has the value V0 between the instants t3 and t4, the value V1 between the instants t4 and t5, the value V2 between the instants t5 and t6, the value V3 between the instants t6 and t7, the value V4 between the instants t7 and t8, the value V5 between the instants t8 and t9, the value V6 between the instants t9 and t10, and the value V7 after the instant t10.

As can be seen in FIG. 11, the output OUT1 is updated at each rising edge of the signal clk, similarly to the output OUT. The circuits 1 and 3 thus have output signals OUT and OUT1 that are identical.

Further, the power consumption of the circuit 3 of FIG. 10 is lower than the power consumption of the circuit 1 of FIG. 9, and the maximum drop of the voltage Vdd is lower in the circuit 3 of FIG. 10 than in the circuit 1 of FIG. 9.

Although not illustrated in a figure, a synchronous shift register 3 may be part of an electronic system or device comprising an emitting circuit configured to provide first data updated at each edge of the first type of the clock signal clk, having a frequency equal to twice the frequency of the signal clk/2, and a receiving circuit configured to receive second data updated at each edge of the first type of the clock signal clk. In such a system, the shift register 3 is for example configured to receive the first data and to provide the second data by shifting the first data in time.

Two specific examples, namely a synchronous counter and a synchronous shift register, of the circuit 3 of FIG. 3 have been described with reference to FIGS. 6 and 9. Those skilled in the art are capable of implementing other circuits 3 having the structure of the circuit 3 of FIG. 3 but providing other functions, such as a linear feedback shift register.

Further, in all the examples previously described, the first type of edge of the signal clk/2, resulting in updates of the flip-flops 300 of the circuit 30, and the second type of edge of the signal clk/2, resulting in updates of the flip-flops 320 of the circuit 32, are respectively rising edges and falling edges. Those skilled in the art are capable of adapting the present description and examples to the case in which the first type of edge is a falling edge and the second type of edge is a rising edge.

In the previous comparisons between the circuits 1 and 3, the output OUT of the circuit 1 is updated at each edge of the first type of the signal clk, the output OUT′ is updated at each edge of the first type of the signal clk/2, having a frequency equal to half the frequency of the signal clk, and the output OUT″ is updated at each edge of the second type of the signal clk/2. In this configuration, the power consumption and the voltage drops ΔVdd are lower in the circuit 3 than in the circuit 1. However, it is also possible that, in the circuit 3, the output OUT′ is updated at each edge of the first type of the signal clk, and the output OUT″ is updated at each edge of the second type of the signal clk. In such a case, the output OUT1 of the circuit 3 is updated at a rate twice as fast as the output of a corresponding circuit 1 synchronized on the first type of edge of the signal clk. In other words, in such a configuration, rather than improving power consumption and reducing voltage drops in the clock tree, the temporal resolution of the circuit 3 is improved by a factor of two with respect to a corresponding circuit 1. For example, if the circuits 1 and 3 both implement shift registers, the shift register 3 processes input data and provides updated output data at a rate twice as fast as the corresponding shift register 1. Similarly, if the circuits 1 and 3 both implement counters, the counter 3 counts at twice the rate of the corresponding counter 1.

Various embodiments and variants have been described. Those skilled in the art will appreciate that certain features of these embodiments can be combined and that other variants will readily occur. In particular, the total number of flip-flops 300 and 320 in the previously described examples of the circuit 3 may differ from the numbers explicitly described above.

Finally, the practical implementation of the embodiments and variants described herein is within the capabilities of those skilled in the art based on the functional description provided above, in particular with respect to the implementation of the circuits 302, 322, and 34.

1. A synchronous circuit, comprising:
a plurality of flip-flops configured to provide an updated output at each edge of a first type of a first clock signal:
a first circuit comprising first flip-flops of the plurality of flip-flops, the first flip-flops being synchronized and updated on a first type of edges of a second clock signal having a frequency equal to half of the frequency of the first clock signal, the first circuit being configured to provide a first output updated at each first type edge of the second clock signal;
a second circuit comprising second flip-flops of the plurality of flip-flops, the second flip-flops being synchronized and updated on a second type of edges of the second clock signal, the second circuit being configured to provide a second output updated at each second type edge of the second clock signal; and
a combinational circuit receiving the first and second outputs and being configured to provide the output of the synchronous circuit from the first and second outputs.

2. The synchronous circuit of claim 1, wherein a number of first flip-flops is equal to a number of second flip-flops.

3. The synchronous circuit of claim 1, wherein the first circuit comprises more than one first flip-flop, and the second circuit comprises more than one second flip-flops.

4. The synchronous circuit of claim 1, wherein the first and second circuits each has a same functionality.

5. The synchronous circuit of claim 1, wherein each first flip-flop is configured to maintain its output between each two updates of said first flip-flop, each second flip-flop being configured to maintain its output between each two updates of said second flip-flop.

6. The synchronous circuit of claim 1, wherein the first flip-flops are series coupled in the first circuit and the second flip-flops are series coupled in the second circuit.

7. The synchronous circuit of claim 1, wherein the first output is determined by at least one output of the first flip-flops, and the second output is determined by at least one output of the second flip-flops.

8. The synchronous circuit of claim 1, wherein the synchronous circuit is a synchronous counter.

9. The synchronous circuit of claim 8, wherein the first circuit is a first synchronous counter, the second synchronous circuit is a second synchronous counter, and the combinational circuit is an adder circuit configured to add the first and second outputs and to provide the output of the synchronous circuit equal to result of the addition.

10. The synchronous circuit of claim 8, wherein:
the first circuit comprises, for each first flip-flop, a circuit providing an input of said first flip-flop based on at least one output among the outputs of the first flip-flops, said at least one output comprising the output of said first flip-flop; and
the second circuit comprises, for each second flip-flop, a circuit providing an input of said second flip-flop based on at least one output among the outputs of the second flip-flops, said at least one output comprising the output of said second flip-flop.

11. The synchronous circuit of claim 1, wherein the synchronous circuit is a shift register.

12. The synchronous circuit of claim 11, wherein the first circuit is first shift register, the second circuit is a second shift register, the combinational circuit is configured to provide the output of the synchronous circuit equal to the first output of the first circuit when the second clock signal is in a state following each edge of the second type of the second clock signal, and equal to the second output of the second circuit when the second clock signal is in a state following each edge of the first type of the second clock signal.

13. The synchronous circuit of claim 12, wherein:
the first flip-flops are series connected, a first one of the first flip-flops has an input receiving an input of the synchronous circuit and each of the other first flip-flops has an input connected to an output of the previous first flip-flop, a last one of the first flip-flops has an output providing the first output; and
the second flip-flops are series connected, a first one of the second flip-flops has an input receiving the input of the synchronous circuit and each of the other second flip-flops has an input connected to an output of the previous second flip-flop, a last one of the second flip-flops has an output providing the second output.

14. A system, comprising:
an emitting circuit configured to provide first data updated at each edge of the first type of the first clock signal;
a receiving circuit configured to receive second data updated at each edge of the first type of the first clock signal; and
a synchronous circuit configured to receive the first data and to provide the second data by shifting the first data, the synchronous circuit comprising:
a plurality of flip-flops, and being configured to provide an updated output at each edge of a first type of a first clock signal:
a first circuit comprising first flip-flops of the plurality of flip-flops, the first flip-flops being synchronized and updated on a first type of edges of a second clock signal having a frequency equal to half of the frequency of the first clock signal, the first circuit being configured to provide a first output updated at each first type edge of the second clock signal;
a second circuit comprising second flip-flops of the plurality of flip-flops, the second flip-flops being synchronized and updated on a second type of edges of the second clock signal, the second circuit being configured to provide a second output updated at each second type edge of the second clock signal; and
a combinational circuit receiving the first and second outputs and being configured to provide the output of the synchronous circuit from the first and second outputs.

15. The system of claim 14, wherein the first circuit comprises more than one first flip-flop, and the second circuit comprises more than one second flip-flops.
